(19) United States
(12) Patent Application Publication
(10) Pub. No.: US 2017/0291580 A1
(43) Pub. Date: Oct. 12, 2017

(54) HEATING ELEMENT INCLUDING CARBON NANOTUBE (CNT) LAYER

(71) Applicants: Santhosh Kumar Loganathan, Belleview, FL (US); Virginie Rollin, DeLand, FL (US); Daewon Kim, Ormond Beach, FL (US)

(72) Inventors: Santhosh Kumar Loganathan, Belleview, FL (US); Virginie Rollin, DeLand, FL (US); Daewon Kim, Ormond Beach, FL (US)

(21) Appl. No.: 15/484,943

(22) Filed: Apr. 11, 2017

Related U.S. Application Data
(60) Provisional application No. 62/320,975, filed on Apr. 11, 2016.

(51) Int. Cl. B60S 1/02; B05D 1/02; B05D 1/18; H05B 3/14; H05K 1/03; H05K 1/09; H05K 3/12; H05B 3/84; B05D 1/00; H05K 1/02

(52) U.S. Cl. CPC B60S 1/026; B05D 1/005; B05D 1/02; B05D 1/18; H05K 1/0212; H05K 1/0306; H05K 1/0274; H05K 1/09; H05K 3/12; H05B 3/84; H05B 3/14; H05K 2201/0108; H05K 2201/0323; H05B 2203/017

(57) ABSTRACT

Apparatus, materials, and techniques and techniques herein can include providing a deposited layer comprising a composite material including carbon nanotubes (CNTs). According to various examples, the composite can be applied to a substrate such as using a solution containing CNTs and other constituents such as sulfur. The solution can be spray-applied to a substrate, or spin-coated upon a substrate, such as to provide a uniform, conductive, and optically-transparent film layer. In one application, such a film layer can be clad or otherwise assembled in a stack-up including a substrate and cover layer (e.g., glass layers), such as to provide a transparent assembly. Such an assembly can include a portion of a window, such as a windscreen for a vehicle, where the CNT material can provide a conduction medium for Joule heating.

### CLAIM OF PRIORITY

This patent application claims the benefit of priority of Loganathan et al., U.S. Provisional Patent Application Ser. No. 62/320,975, titled “Carbon Nanotube Composites,” filed on Apr. 11, 2016 (Attorney Docket No. 4568.002PRV) which is hereby incorporated by reference herein in its entirety.

### BACKGROUND

Transparent conductive film (TCF) and transparent heated glass can be used in a wide range of applications such as for solar voltaic cells, thermally-based sensors, or window defrosters and demisters, as illustrative examples. Generally-available transparent heating assemblies include use of an optically-transparent conductive film. Indium tin oxide (ITO) is one material that is generally available and used in transparent heaters (with transmittance, T>95%), particularly ITO-based heaters in windscreens for vehicular applications.

### SUMMARY OF THE DISCLOSURE

Apparatus, materials, and techniques and techniques herein can include providing a deposited layer (e.g., a coating) comprising a composite material including carbon nanotubes (CNTs). According to various examples, the composite can be applied to a substrate such as using a solution containing CNTs and other constituents such as sulfur. The solution can be spray-applied to a substrate, dip coated upon the substrate, or spin-coated upon a substrate, such as to provide a uniform, conductive, and optically-transparent film layer. In one application, such a film layer can be clad or otherwise assembled in a stack-up including a substrate and cover layer (e.g., glass layers), such as to provide a transparent assembly. Such an assembly can include a portion of a window, such as a windscreen for a vehicle, where the CNT material can provide a conduction medium for Joule heating. Use of a spray-coated or spin-coated CNT solution is compatible with generally-available windscreen materials and assemblies, so such assemblies can be fabricated to include one or more CNT material layers without requiring chemical vapor deposition (CVD).

In an example, a technique such as a method can include depositing a solution on a substrate, the solution including carbon nanotubes, sulfur, and a solvent. The technique can include drying the solution to provide a conductive layer on the substrate, and forming two electrodes on the substrate in electrical contact with the conductive layer to provide a heating element. In an example, the method can include depositing multiple conductive layers comprising carbon nanotubes functionalized with sulfur on the substrate.

In an example, a heating element assembly can include a substrate, a conductive layer including carbon nanotubes and sulfur, formed upon the substrate, and two electrodes electrically coupled to the conductive layer, the two electrodes, when energized, configured to establish a current through the conductive layer to provide a heating element. The heating element assembly can be included as a portion of a structure in a vehicle, such as an automobile, boat or ship, locomotive, or an aircraft, as illustrative examples. The heating element assembly can include an optically-transparent substrate and the conductive layer can also be optically transparent, such as for use as a demisting, defrosting, or deicing element located within, applied to, or included as a portion of a windscreen. Other applications include leading edge deicing for airfoils, such as included as portions of an aircraft wing, stabilizer, elevator, or wind turbine blade airfoil, as illustrative examples. Such a heating element can be connected to a control circuit, such as in a system having one or more of a moisture or temperature sensor to provide closed-loop control of the heating element to reduce or suppress icing or enhance visibility.

This summary is intended to provide an overview of subject matter of the present patent application. It is not intended to provide an exclusive or exhaustive explanation of the invention. The detailed description is included to provide further information about the present patent application.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1A and FIG. 1B illustrate generally views of an example of a heating element assembly that can include a conductive layer comprising carbon nanotubes.

FIG. 2 illustrates generally an example of a heating element assembly that can include a conductive layer comprising carbon nanotubes, such as coupled to an energy source.

FIG. 3 illustrates generally an illustrative example of an Energy Dispersive X-ray Spectroscopy (e.g., “EDS” or “EDX”) scan indicative of a composition of a solution including carbon nanotubes and sulfur.

FIG. 4 illustrates generally an illustrative example of a scanning electron microscope (SEM) image such as showing a location for which a point spectrum EDX analysis can be performed on a carbon nanotube structure present in solution.

FIG. 5 illustrates generally an illustrative example an SEM image illustrating generally respective dimensions of carbon nanotubes present in a solution.

FIG. 6A illustrates generally a line-spectrum EDX obtained along a line as shown in FIG. 6B, providing an illustrative example of a sulfur blending signature in a carbon nanotube structure in solution.

FIG. 7 illustrates generally a technique, such as a method, that can include forming a carbon nanotube film layer on a substrate.

FIG. 8 illustrates generally an infrared thermal image of an operating heating element, obtained by a thermal camera and showing the temperature distribution profile, where brighter portions of the image represent higher surface temperature as compared to darker portions of the image.

FIG. 9 illustrates generally a representation of the user interface for the FLIR ResearchIR Max software (available from FLIR Systems, Inc., Wilsonville, Oreg., USA), such as can be used for performing data acquisition, and as was used for obtaining experimental results relating to illustrative examples described herein.

FIG. 10A illustrates generally an illustrative example showing a decrease in optical transmittance as a count of a number of carbon nanotube layers increases.

FIG. 10B illustrates generally an illustrative example showing a decrease in sheet resistance as a count of a number of carbon nanotube layers increases.

FIG. 11 illustrates generally an illustrative example showing a negative temperature coefficient of sheet resistance as an operating temperature of a heating element including a carbon nanotube structure increases.

FIG. 12 illustrates generally an illustrative example showing a thermal cycling behavior of a heating element including a carbon nanotube structure.

FIG. 13 illustrates generally an illustrative example showing respective temperature versus time profiles for heating elements having different counts of layers of carbon nanotubes.

FIG. 14A, FIG. 14B, and FIG. 14C illustrate generally respective illustrative examples showing temperature versus time profiles for heating elements having different counts of layers of carbon nanotubes, where the trends are plotted over a longer time duration as compared to FIG. 13.

FIG. 15A and FIG. 15B illustrate generally respective infrared thermal images of an operating heating element, such as before application of a thermal tape in FIG. 15A, and after application of a thermal tape in FIG. 15B.

FIG. 16A, FIG. 16B illustrate generally respective infrared thermal images of an operating heating element, such as before application of a thermal tape in FIG. 16A, and after application of a thermal tape in FIG. 16B, and FIG. 16C shows a processed image calculating a difference between FIG. 16A and FIG. 16B at each spatial location, illustrating an improvement in thermal uniformity.

FIG. 17A, FIG. 17B, and FIG. 17C illustrate generally respective histogram plots of the thermal images of an operating heating element, such as corresponding to the image of FIG. 16A before application of a thermal tape.

FIG. 18A, FIG. 18B, and FIG. 18C illustrate generally respective histogram plots of the thermal images of an operating heating element, such as corresponding to the image of FIG. 16B after application of a thermal tape.

FIG. 19A, FIG. 19B, FIG. 19C, FIG. 19D, FIG. 19E, and FIG. 19F illustrate generally respective infrared thermal images of an operating heating element corresponding to various operating temperatures.

FIG. 20A and FIG. 20B illustrate generally temporal plots of temperature versus time for each of the spatial locations shown in FIG. 19B, where FIG. 20A includes each of the nine cursor locations, and FIG. 20B includes a subset of the cursor locations.

### DETAILED DESCRIPTION

The present inventors have recognized, among other things, that conductive films such as including Indium Tin Oxide (ITO) can have disadvantages, particularly when used for heating applications. Such disadvantages can include a slow thermal response, mechanical brittleness, and a high cost of manufacturing. Other drawbacks can also exist, such as interference of the ITO coating with radio transmission, such as can adversely affect radio and mobile phone reception or transmission through a surface including an ITO coating. Cloudiness, humidity, wind, and exposure to fluids, such as during washing, can also affect the performance of such coatings.

In another approach, transparent heaters can be fabricated using carbon nanotubes (CNTs). CNTs can provide one or more of excellent optical transparency, high conductivity (e.g., on the order of 10⁶ Siemens per meter (S/m) or greater), mechanical flexibility, and the raw material used to produce CNTs is abundant. At temperatures of less than about 350° C., CNTs are generally thermally stable in the presence of an oxygen environment. At a temperature beyond about 350° C., CNTs may degrade at least in part due to oxidation because the CNTs are structures comprising carbon atoms. In a vacuum environment, the CNTs can endure up to about 3726° C. or even higher temperatures, such as due to the presence of sp2 hybridized carbon-carbon bonds in CNT structures.

When an electric current is applied through a conductive material, the applied electric current will induce a Joule heating effect, which can be referred to as a self-heating or resistive heating effect. The electric current will cause the traveling electrons to bounce off the atoms of the conductive element and make them vibrate. This vibration rate will create the rise in temperature. A tungsten filament inside an incandescent light bulb is an illustrative example of such heating, where the heating is used to produce light. The thermal output will vary depending upon the conductive nature of the element. Generally, a highly conductive material will produce less Joule heating whereas a highly resistive material will produce a comparatively greater Joule heating effect. Generally, as mentioned above, CNTs are excellent electrical conductors, but such CNTs alone may only produce a modest resistive heating effect.

In one approach, such as to provide a CNT layer for a heating apparatus, CNT material can be grown on a substrate using a chemical vapor deposition. For an application where the CNT material is part of a transparent assembly, a glass can be used as a substrate for CVD. However, such an approach can present challenges. For a vehicular application or another application where the substrate glass occupies a significant area (such as a windscreen for a vehicle or a mother glass for an electronic device such as a display or light source), it is generally not possible to use CVD apparatus enclosing the entire substrate. In another approach, CNTs can be formed on smaller wafers and transferred to a larger substrate. However, this approach can also have disadvantages, such as causing non-uniformity and layer deterioration. Growing CNTs in smaller scale can also incur significant costs.

For heating applications, the Joule heating effect of CNTs can be enhanced by functionalizing the CNTs with an insulating material to increase a resistivity of a film including the functionalized CNT compound. Such a functionalized compound can be included as a portion of a heating element. The present inventors have recognized, among other things, that a composite including CNTs can be used, such as to facilitate fabrication of assemblies that would otherwise be impractically large for CVD processing. Such a composite can also provide enhanced heating efficiency when used as a portion of a heating element. In an example, a CNT material can be functionalized with sulfur. A solution containing a mixture of single-walled nanotubes (SWNT), double-walled nanotubes (DWNT), and multi-walled nanotubes (MWNT), along with ammonium hydroxide and water, can be used to form a conductive layer as a portion of a heating element. In an illustrative example, such as described herein, such a solution can include about 75% SWNT (such as 75% SWNT by volume). An example of such a solution can be obtained from Brewer Science (Rolla, Mo. USA) under the trade name CNTRENE™ 3021 B3-R.

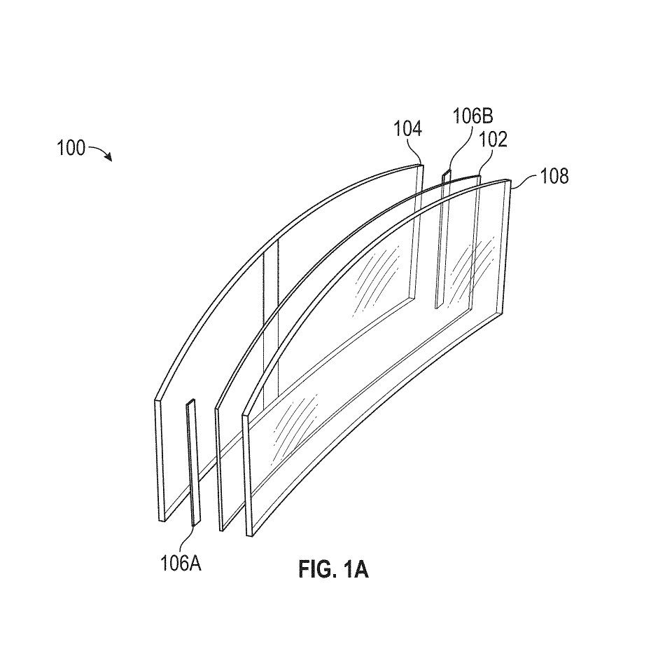

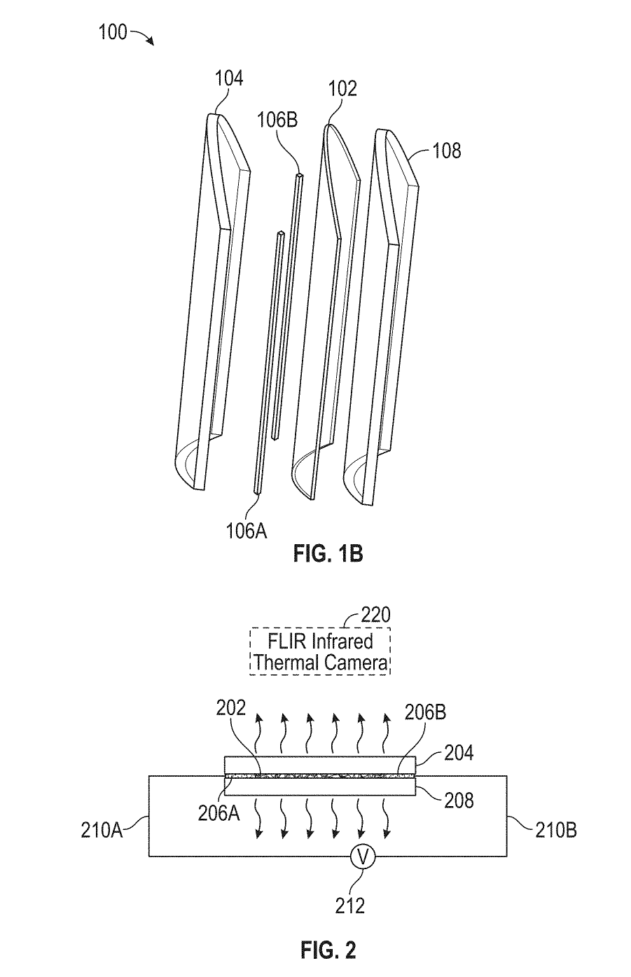

FIG. 1A and FIG. 1B illustrate generally views of an example of a heating element assembly 100 that can include a conductive layer 102 comprising carbon nanotubes (CNTs) such as deposited on a substrate 108, along with two or more electrodes, such as a first electrode 106A and a second electrode 106B. A cover layer 104 can be included, such as comprising the same material as the substrate 108, or a similar material. As an illustrative example, the substrate 108 can include windscreen glass or another material such as polycarbonate. The CNT layer 102 can have a thickness in the range of a few micrometers. The electrodes 106A and 106B can contact the CNT layer 102, such as at the edges. Materials for the electrode can include one or more of copper, silver, tungsten, aluminum, or one or more other materials. The cover layer 104 can include one or more of another glass layer, a non-reactive protective coating, or an anti-scratch, high thermal performance one-sided tape (e.g., an adhesive-backed flexible polymer). Other structural configurations and materials can be used to provide optically-transparent assemblies as described herein, such as without requiring a glass substrate or cover layer. For example, a cover layer including one or more of polymethyl methacrylate (PMMA) or polycarbonate (PC) can be used, such as a ProTEK PSR-R (available from Brewer Science). Such a polymer-based coating can also provide transparency, temperature stability, and compatibility for retaining the CNTRENE™-coated layer properties, such as to provide a flexible heating element that can also be optically transparent.

FIG. 2 illustrates generally an example of a heating element assembly that can include a conductive layer 202 comprising carbon nanotubes, such as coupled to an energy source 212 (e.g., a voltage source). The configuration shown in FIG. 2 illustrates generally a prototype heating element that was used for obtaining the experimental results described generally herein. In the example of FIG. 2, a substrate 208 can include a glass substrate, and a cover layer 204 such as glass or a polymer can be used, according to various examples. Electrical interconnects (such as wires 210A and 210B) can be used to couple the source 212 to the conductive layer 202. The conductive layer 202 can include one or more CNT layers formed upon the substrate 208, such as comprising a sulfur-functionalized CNT composite.

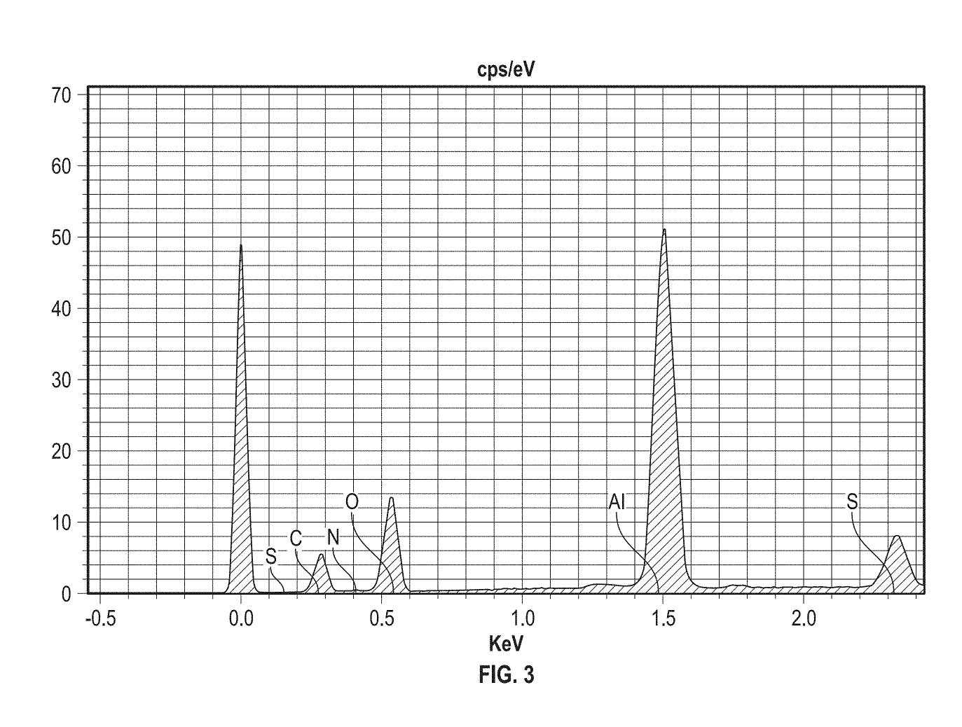

FIG. 3 illustrates generally an illustrative example of an Energy Dispersive X-ray Spectroscopy (e.g., “EDS” or “EDX”) scan indicative of a composition of a solution including carbon nanotubes and sulfur. As mentioned elsewhere herein, by functionalizing CNTs with sulfur, a suitable CNT film layer can be deposited having resistance characteristics appropriate for Joule heating. An example of a sulfur-functionalized solution suitable for use in deposition is CNTRENE™ 3021 B3-R available from Brewer Science. In the CNTRENE™ 3021 B3-R solution, an average length of CNT is approximately 0.4 to 0.6 micrometers (μm). To functionalize the CNTs with sulfur, carbon and sulfur-based gases can be introduced during the CNT growth process. Sulfur is generally insoluble in water and many other solutions, but carbon disulfide provides a solution containing sulfur. Without being bound by theory, it is believed that in at least one approach, functionalization can be performed by introducing carbon disulfide gas, which was the source of sulfur during production of carbon nanotubes. The CNTRENE™ solution contains a mixture of sulfur-functionalized single-walled nanotubes (SWNT, ˜75%), double-walled nanotubes (DWNT) and multi-walled nanotubes (MWNT) with ammonium hydroxide and water.

EDX spectroscopy as shown in FIG. 3 was performed using a Bruker EDX scan system in an FEI Quanta 650 scanning electron microscope. A surface morphology of a material and its chemical composition can be studied by using EDX. This method is based on the X-ray source interaction upon the sample material surface. A high beam of electron source can be focused on the sample and will excite an atom from an unexcited ground state. Then, the electrons from the outer high-energy shell will fill the gap. This tends to create an energy difference and releases an X-ray. This energy difference is measured by the analyzer in the EDX system. Each element in the periodic table holds its own energy spectrum, which can be quantitatively measured and displayed.

The elemental analysis of the CNTRENE™ solution was performed using an EDX scan, where EDX was used to measure qualitative and quantitative elemental composition at the nanoscale. A quantity of 0.5 milliliters (ml) of the CNTRENE™ solution was dropped on an aluminum stub and left to dry for 24 hours, then loaded and scanned. As shown in FIG. 3, sulfur is present in the solution, confirming the doping process of the CNTs. The EDX spectrum of FIG. 3 illustrates a plot of X-ray counts versus energy (in Kilo-electronVolts (KeV)). The test also reveals the presence of aluminum and oxygen. The presence of oxygen was due to the ammonium hydroxide and the presence of sulfur was due to the functionalization of the carbon nanotubes. The high concentration of aluminum is attributed to the stub. The spectrum of FIG. 3 illustrates a presence of sulfur in the dried solution. Sulfur can generally be regarded as an electrical insulator and an electrical resistivity of sulfur is high (e.g., on the order of about 1×10¹⁵Ω m).

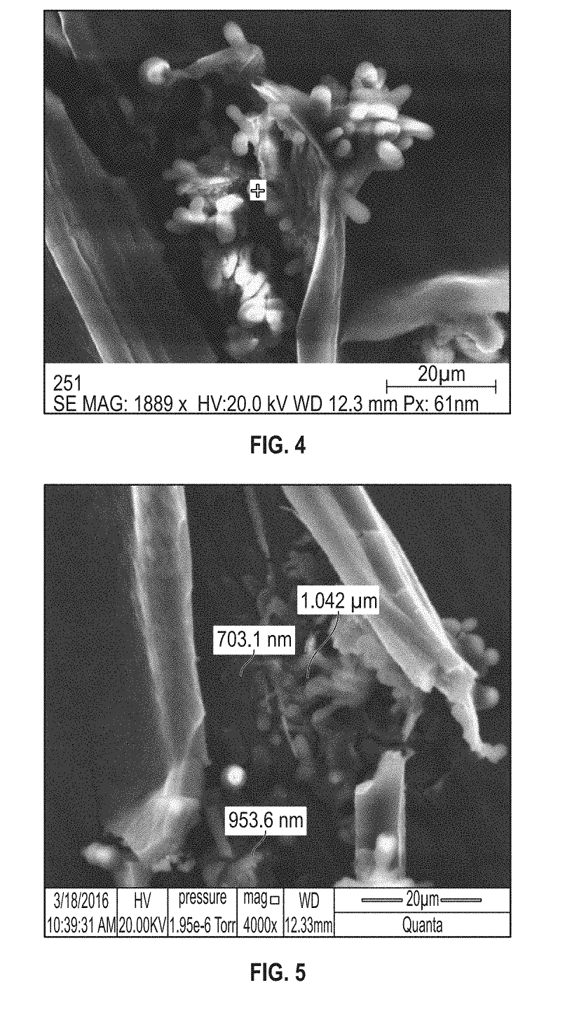

FIG. 4 illustrates generally an illustrative example of a scanning electron microscope (SEM) image such as showing a location for which a point spectrum EDX analysis can be performed on a carbon nanotube structure present in a dried sample of solution and FIG. 5 illustrates generally an illustrative example an SEM image illustrating generally respective dimensions of carbon nanotubes present in the dried solution. Generally, a diameter of CNTs is approximately 900 nm as shown in FIG. 4 and FIG. 5.

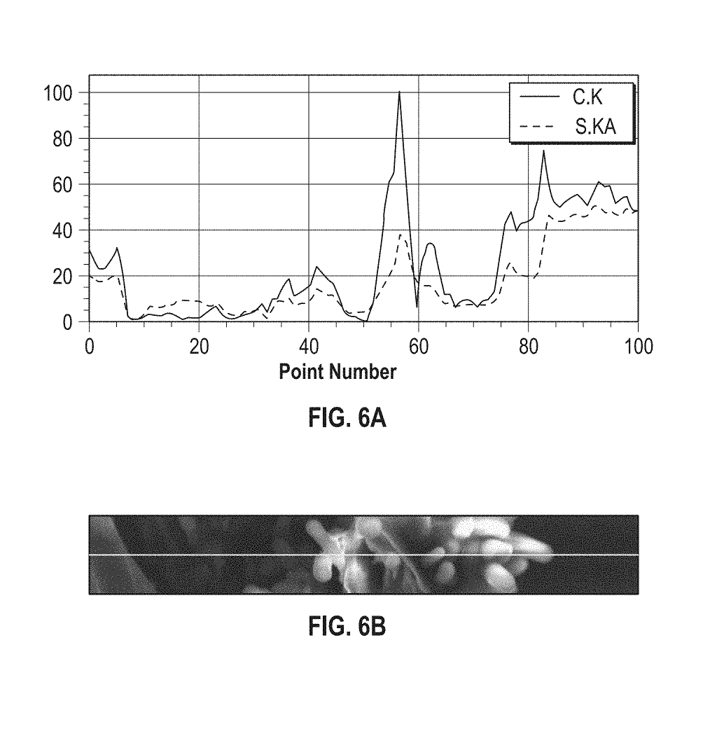

FIG. 6A illustrates generally a line-spectrum EDX obtained along the white line as shown in FIG. 6B, providing an illustrative example of a sulfur blending signature in a carbon nanotube structure in solution. The proportion of carbon is higher than sulfur, which is used to functionalize the CNT, particularly in regions where the line spectra show spatially-overlapping carbon and sulfur fractions.

A layer of carbon nanotubes creates a conductive medium between electrode locations, and a presence of sulfur functionalization modulates a resistance of the conductive medium. This helps produce a high temperature output for the applied voltage, compared to a CNT film lacking such functionalization. Referring back to FIG. 3, a presence of nitrogen and oxygen in the EDX scan chart was due to ammonium hydroxide [NH₄OH] in the solution. Hydrogen cannot be detected using an EDX scan, and is thus absent from the results. There are multiple reasons for the use of ammonium hydroxide, including that it serves as a dispersant. Functionalized carbon nanotubes are prone to attract and stick together with nearby carbon nanotubes, but this can be suppressed such as by using an ammonium hydroxide solution. Ammonium hydroxide can also create a hydroxide environment by engaging all hydrogen and oxygen elements in the solution. The name ammonium hydroxide shows an alkali with composition: [NH₄⁺][OH⁻]. This, in turn avoids the formation of sulfur dioxide and carbon dioxide gases, from the reaction shown below.

CS₂+3O₂→CO₂+2SO₂ EQN. 1

Use of ammonium hydroxide in the CNT solution can also provide a uniform coating during the spin coating process. A surface tension of ammonium hydroxide is low as compared to other media and accordingly, use of ammonium hydroxide promotes spreading of the solution on a glass substrate. Without being bound by theory, it is believed that ammonium hydroxide can also provide or enhance a bonding effect between the self-adhering carbon nanotubes and a substrate surface. TABLE 1, below, illustrates generally results obtained from performing a point-spectrum EDX scan of a glass substrate coated with CNTRENE™ solution.

TABLE 1

| | Point Spectrum EDX Scan | | | | |
|---|---|---|---|---|---|
| | Atomic | | Norm. C | Atom. C | (1 Sigma) |
| Element | Number | Series | [wt. %] | [at. %.] | [wt. %] |
| Oxygen | 8 | K-series | 33.33 | 31.32 | 3.37 |
| Carbon | 6 | K-series | 43.94 | 55.01 | 4.47 |
| Sulfur | 16 | K-series | 10.25 | 4.81 | 0.33 |
| Aluminum | 13 | K-series | 8.78 | 4.89 | 0.38 |
| Nitrogen | 7 | K-series | 3.70 | 3.97 | 0.66 |
| | | Total | 100.00 | 100.00 | |

Various techniques can be used to form a CNT film on a substrate, such as comprising a sulfur-functionalized CNT film having constituents as shown above in the illustrative example of TABLE 1. Such techniques can include one or more of dip coating, spray coating (e.g., using a spray pyrolysis technique), or spin coating. Such techniques can be performed repeatedly, such as to form multiple CNT film layers. According to various examples described herein, a transparent heating device can include an conductive optically-transparent CNT layer, such as to provide an optical transmittance of the overall stack-up of substrate, CNT layer (or layers), and a cover layer of over 90% in the visible wavelength spectrum. The phrase “optically transparent” does not require perfect transmittance (e.g., 100% or 1.0), but can refer to any of a variety of specified transmittances, such as at least 80%, at least 85%, or at least 90%, as illustrative examples.

Dip Coating

A process including a bath immersion can be used where a substrate is dipped in a coating material. A dip coating technique allows relatively easy control of thickness as compared to other approaches. Such control can be achieved by adjusting one or more different variables including a count of dip operations, a withdrawal velocity, a substrate surface characteristic, a contact angle of the solution to the substrate, a solution temperature, and a concentration of the solution to be coated. Such an approach is suitable for a double-sided coating with high uniformity and precision thickness control but such a process may be more time consuming as compared to other approaches described herein. A dip withdrawal can be performed at a constant rate, such as in order to avoid defects such as unwanted micro-patterns.

Spray Coating

A spray coating technique can also be used. As an illustrative example, a substrate having dimensions of 25 millimeters (mm)×25 mm can be treated with ethanol. The substrate can then be loaded in a spray coating machine (for example, Spray Pyrolysis Automated Equipment), chuck temperature, ambient temperature, and pressure can be controlled. To achieve a uniform coating the nozzle flow rate of 5 ml/min was used, according to an illustrative example. An ultrasonic transducer can be included at a distal tip of a spray nozzle, such as to atomize the solution which is then deposited on the surface of the substrate. The lateral velocity and the number of consecutive sprays can be used to precisely control a thickness of the layer. As an illustrative example, for large-scale commercial manufacturing to provide a uniform coating, a spray coating process can be used.

Spin Coating

Use of a spin coating technique generally provides a uniform and thin layer of coating. The thickness of each layer can be controlled by adjusting one or more of the applied rotational velocity of the spin coater (in revolutions per minute (RPM)), a duration of spinning, and the operating temperature (e.g., a chuck temperature). A thickness of the coating layer is generally inversely proportional to the rotational velocity (e.g., “spin speed”). For example, a thin layer can be produced using a relatively higher RPM range, and at relatively lower RPM range, the thickness will be high, for the same operating duration. The CNTRENE™ solution mentioned above was observed as suitable for spin coating, and other operations such as a spray coating.

A spin coating technique can be performed using one or more of a static dispense technique or a dynamic dispense technique. Generally, a small puddle of fluid is dropped at the center of a spinning substrate. Fluid dispensed on the surface can propagate outward, and some proportion flows off an edge of the substrate. As mentioned above, a thickness of a resulting film can depend on multiple parameters, such as including a spin duration, a spin RPM, an acceleration rate, a surface tension of the solution, an amount of solution, an evaporation rate, and temperature of a chuck or the surrounding environment. In order to achieve a desired thickness and precision, spin coating is generally performed in a controlled environment. In a static dispense technique, a small puddle of solution is generally dropped at the center of the substrate while the chuck or stage is in a static condition. An amount of dispensed solution can be selected based upon a concentration of the solution and an area of the substrate to be coated. In the dynamic dispense technique, a small puddle can be applied on the substrate, such as mostly or entirely in the center of the substrate while the stage is rotating. A modified static dispense technique was used for the prototypes from which experimental data was obtained herein.

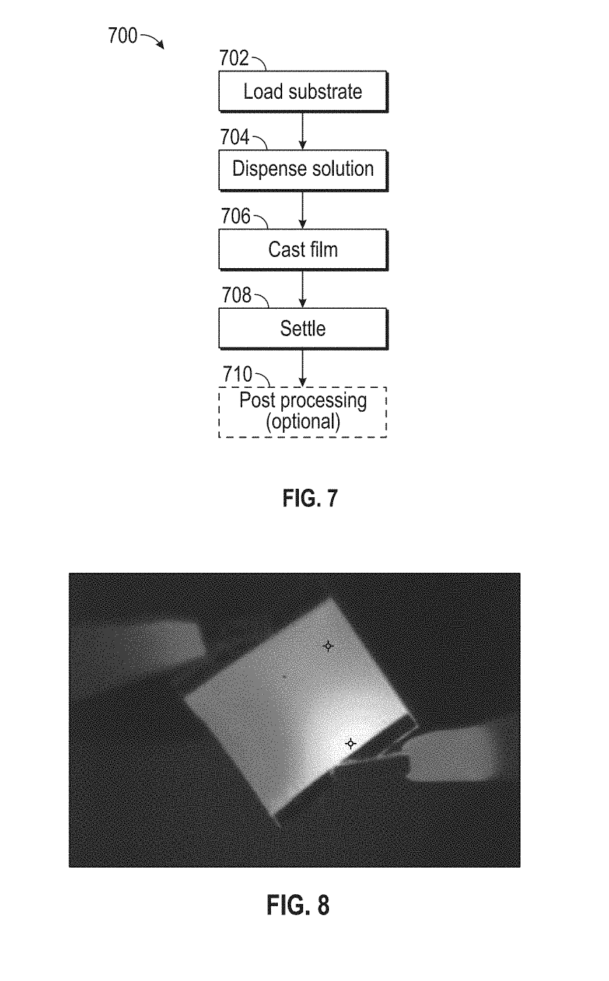

FIG. 7 illustrates generally a technique 700, such as a method, that can include forming a carbon nanotube film layer on a substrate. At 702, a substrate can be loaded for processing, such as placed in a chuck or stage. At 704, a coating solution can be dispensed on the substrate. At 706, a film can be cast such as by rotating the stage or chuck, and at 708, the film can be allowed to settle. At 710 further processing can occur, such as providing additional rotation (e.g., spinning) to achieve a desired film uniformity or thickness. Other processing steps can include film curing or isolation.

FIG. 8 illustrates generally an infrared thermal image of an operating heating element, obtained by a thermal camera and showing the temperature distribution profile, where brighter portions of the image represent higher surface temperature as compared to darker portions of the image. The CNT layer in the structure imaged in FIG. 8 was formed on a transparent glass substrate having dimensions of 25 mm×25 mm. In this illustrative example, a one-sided adhesive copper tape is used as an electrode material, and the electrodes are placed at opposite edges of the CNT-coated transparent glass. A multi-meter can be used to measure the resistance of each specimen. The transmittance of each specimen can be measured, such as by using an Evolution™ 260 Bio UV-Visible spectrophotometer (available from Thermo Fisher Scientific Inc., Waltham, Mass., USA). A forward-looking infrared (FLIR) thermal imaging camera can be used to capture the thermography of the specimen, such as to obtain an image as shown in FIG. 8 and as shown in other examples described herein.

For the examples imaged in FIG. 8 and other examples below, a spin coating technique was used to produce the heating element. A CNT-based film can be obtained on a glass substrate by spin coating the substrate using a Chemat KW-4A spin coater (available from Chemat Technology, Inc., Northridge, Calif., USA). The substrate (e.g., a glass slide) was examined closely for any sort of imperfection such as small scratch and pits. The slide was then treated with ethanol to get rid of atmospheric dust and fingerprints. The ethanol treatment can provide better adhesion between the glass and CNT material, though the CNT material has a self-interconnections and self-adhering capability. In an illustrative example, the ethanol treated slide was baked at 250° C. for 5 minutes and cooled to room temperature for 2 minutes. After cooling down, the slide is loaded into the spin coater chuck where the glass slide is placed rigidly using a vacuum suction technique. The CNTRENE™ solution mentioned above is applied on the entire surface of the transparent glass. In this illustrative example, a static dispense coating mechanism is used including a pipette positioned at 45 degrees with respect to the substrate for improved visibility and dispersion rate. To get rid of excess coating material, a quick spin of 2000 RPM was applied for 1 second at a ramp rate of 10000 RPM/sec. Then, the coating was allowed to cool at low RPM. The substrate was post-baked to 250° C. for 5 minutes and cooled to room temperature for 2 minutes. This provided uniform coating and additional layers could then be coated using a similar procedure, without requiring ethanol treatment between coating operations. In another illustrative example, the slide is loaded into the spin coater chuck where the glass slide is placed rigidly using a vacuum suction technique, without requiring pre-baking. The CNTRENE™ solution mentioned above is applied on the entire surface of the transparent glass. To get rid of excess coating material, a quick spin of 2000 RPM is applied for 30 seconds. In these illustrative examples, the one or more CNT-coated layers on the glass substrate are sandwiched by placing another transparent glass with the same dimension on the top. This will isolate the CNT from environment disturbance without losing transmittance.

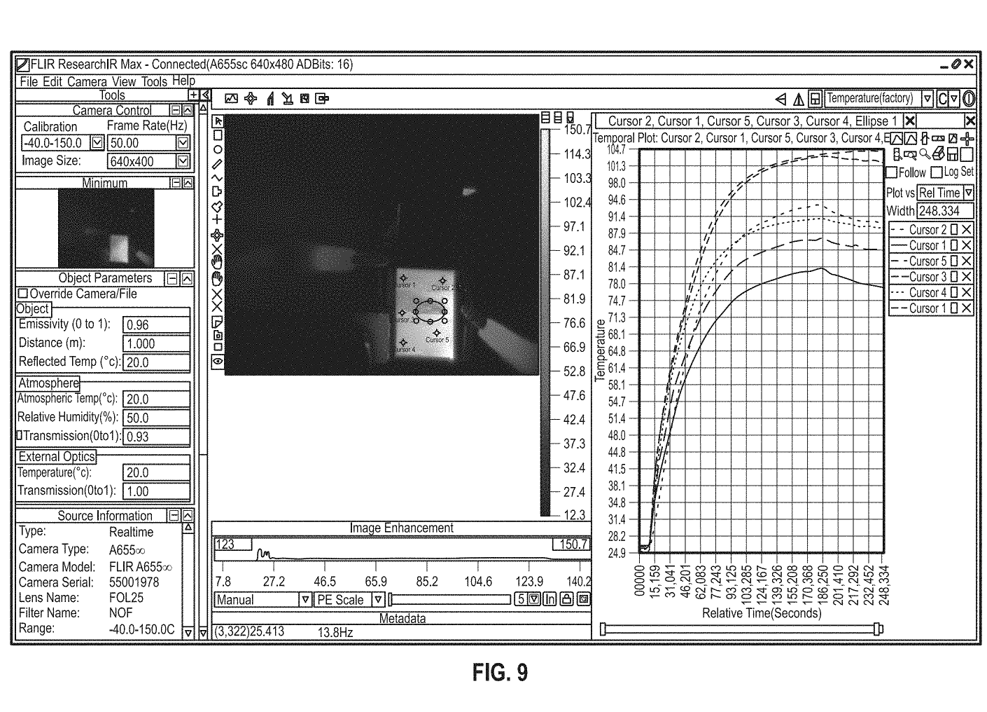

For the experimentally-obtained results herein, a spectral range of 7.5 μm. to 14 μm was used, and FLIR ResearchIR Max software (available from FLIR Systems, Inc., Wilsonville, Oreg., USA) provides a user interface for active thermography and also provides a data acquisition system, as shown in FIG. 9, which illustrates generally a representation of the FLIR ResearchIR Max software. The FLIR ResearchIR Max software was used for obtaining experimental results relating to illustrative examples described herein. To evaluate a thermal performance of the sandwiched heater structure comprising the glass substrates and the CNT material, a DC power source is provided using two 48-Volt DC supplies connected in series. A delivered current and corresponding resistance of the structure-under-test can also be monitored. The two terminals of the voltage source were connected to copper electrodes as described generally above in relation to FIG. 2. A current and resistance can thereby be measured. The FLIR IR camera was used to capture the temperature increment. A surface temperature was measured for the applied voltage, as heat is emitted from the CNT coating.

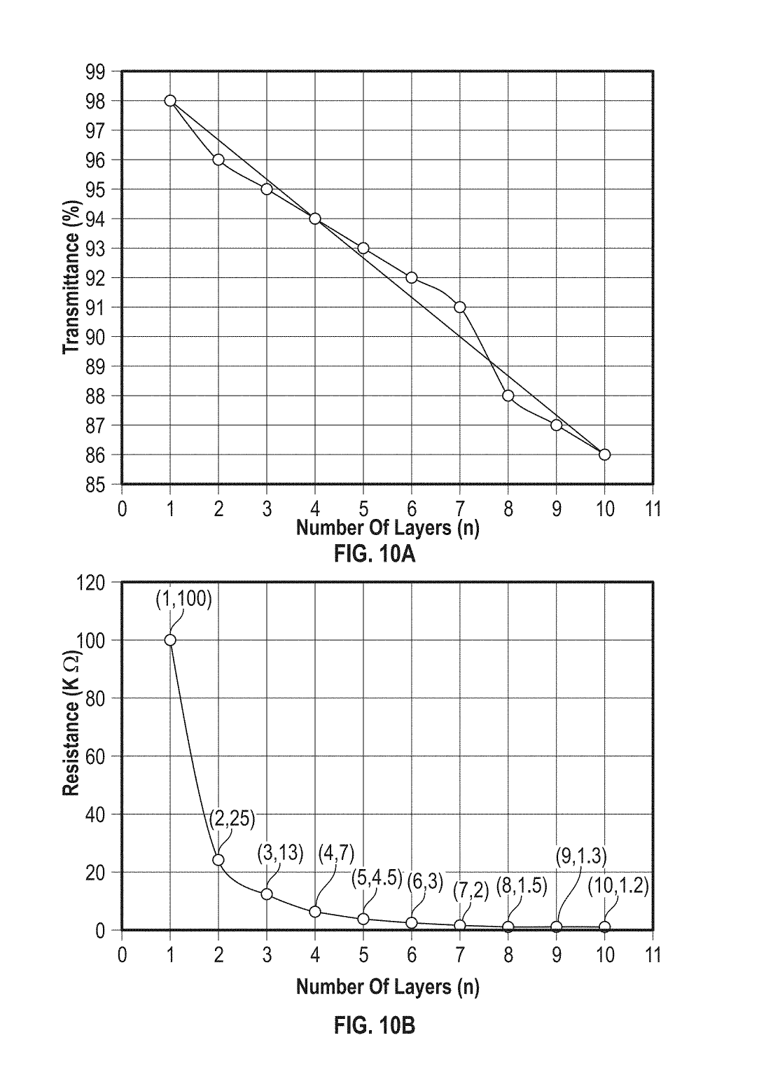

FIG. 10A illustrates generally an illustrative example showing a decrease in optical transmittance as a count of a number of carbon nanotube layers increases. The FLIR thermal camera used for obtaining the result shown in FIG. 10A can be calibrated with an emissivity value corresponding to the materials being measured. The emissivity was assigned as 0.95 because a CNT film can generally be regarded as a near-perfect optical absorption material and generally the emissivity ranges from 0.91-0.95 with respect to the temperature range −40° C. to 300° C. Temperature readings derived from FLIR imaging were verified with a digital thermometer by performing a surface contact method, for the experimentally-obtained observations herein. According to various illustrative examples herein, glass slides uniformly coated with CNTRENE™, such as forming a five-layer CNTRENE™ coated transparent glass heating element, had a sheet resistance of about 3.5 Kilo-ohms (Kf) to about 4.5 KΩ and a transmittance of 93%. A nine-layer CNTRENE™-coated transparent glass heating element provided a sheet resistance of about 1.3 KΩ and a transmittance of 88%.

FIG. 10B illustrates generally an illustrative example showing a decrease in sheet resistance as a count of carbon nanotube layers increases. It is observed that increasing a layer count of CNTRENE™-coated layers correspondingly increases a duration of time to reach a peak (e.g., equilibrium) temperature for a specified applied voltage. Also, the sheet resistance generally decreases as a CNTRENE™ layer count increases, but experimentally-obtained results indicate that after 10 layers there is no significant reduction in both resistance, as shown in FIG. 10B, and possibly due to a transition from sheet to bulk conduction within the coating medium. The labels (n,r) on each point in FIG. 10B indicate a count of layers, “n,” and a corresponding resistance in KΩ, “r.”

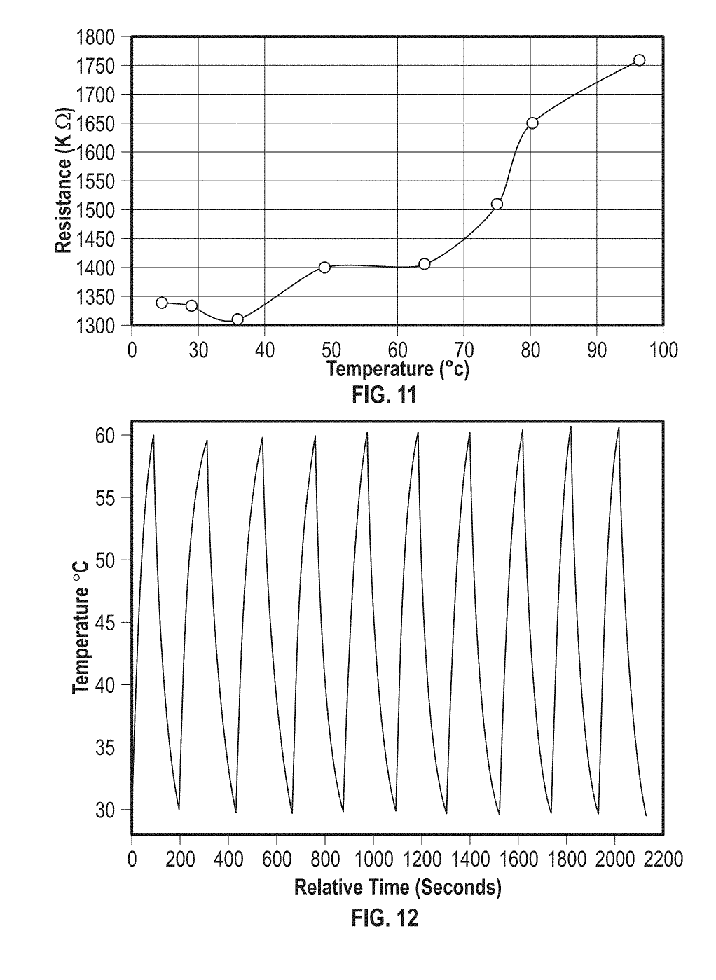

FIG. 11 illustrates generally an illustrative example showing a negative temperature coefficient of sheet resistance as an operating temperature of a heating element including a carbon nanotube structure increases. Electrical resistance of coated layers including CNTs can be influenced by operating temperature. For example, a sheet resistance as shown in FIG. 11 decreased initially with an increasing temperature. Without being bound by theory, this is believed due to a negative thermal coefficient (NTC) effect. Due to the NTC effect, a specimen can increase its temperature rapidly as the voltage was applied, such as initially presenting a higher resistance. The NTC is observed in elements such as carbon, silicon, and germanium. In FIG. 11, the NTC effect is illustrated generally where an initial resistance is high when the heating element is first energized, and then drops before increasing as temperature increases.

FIG. 12 illustrates generally an illustrative example showing a thermal cycling behavior of a heating element including a carbon nanotube structure, including a count of five layers. A voltage of 80 V was applied, then turned off, and then applied again to provide ten successive thermal cycles as shown in FIG. 12. The target cycling range was to achieve a temperature of about 60° C. peak starting from about 30° C. For the FLIR-derived temperature measurements, an emissivity was set to 0.95 and the transmittance was set to 1, because the carbon nanotube side faced towards the infrared camera. A fast heating and cooling response was observed as shown in FIG. 12, and there was no degradation in performance observed during the test. An average cycle took about 210 seconds to reach from about 30° C. to about 60° C. and back down to about 30° C.

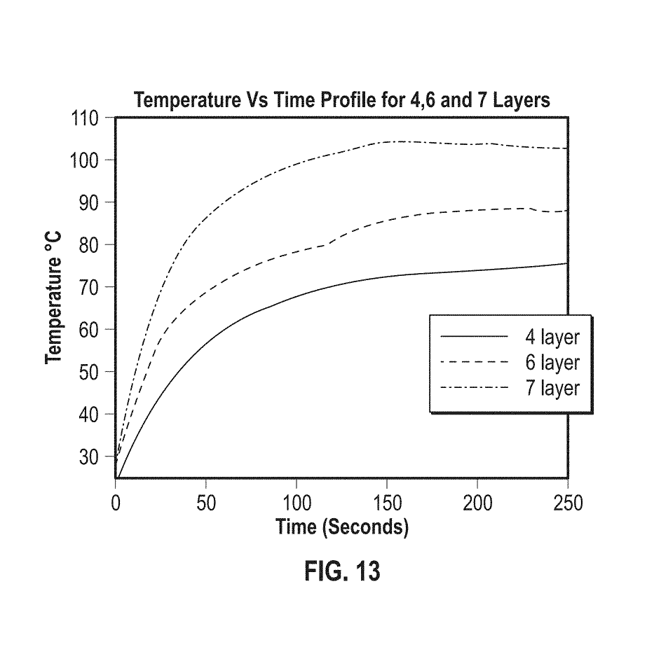

FIG. 13 illustrates generally an illustrative example showing respective temperature versus time profiles for heating elements having different counts of layers of carbon nanotubes. Heating performance can depend upon various factors such as including an overall thickness of a carbon nanotube film formed on a surface of a specimen. A thickness of CNT coating may vary throughout a sample when observed at microscale, such as using SEM. However, temperature profiles recorded for specimens with different counts of deposited CNT layers clearly illustrate a dependence between an equilibrium temperature versus a count of layers. For the experimentally-observed results in FIG. 13, a constant voltage of 120 V was applied and the temperature plot was generated with respect to time in seconds, for deposited layer counts of four, six, and seven layers.

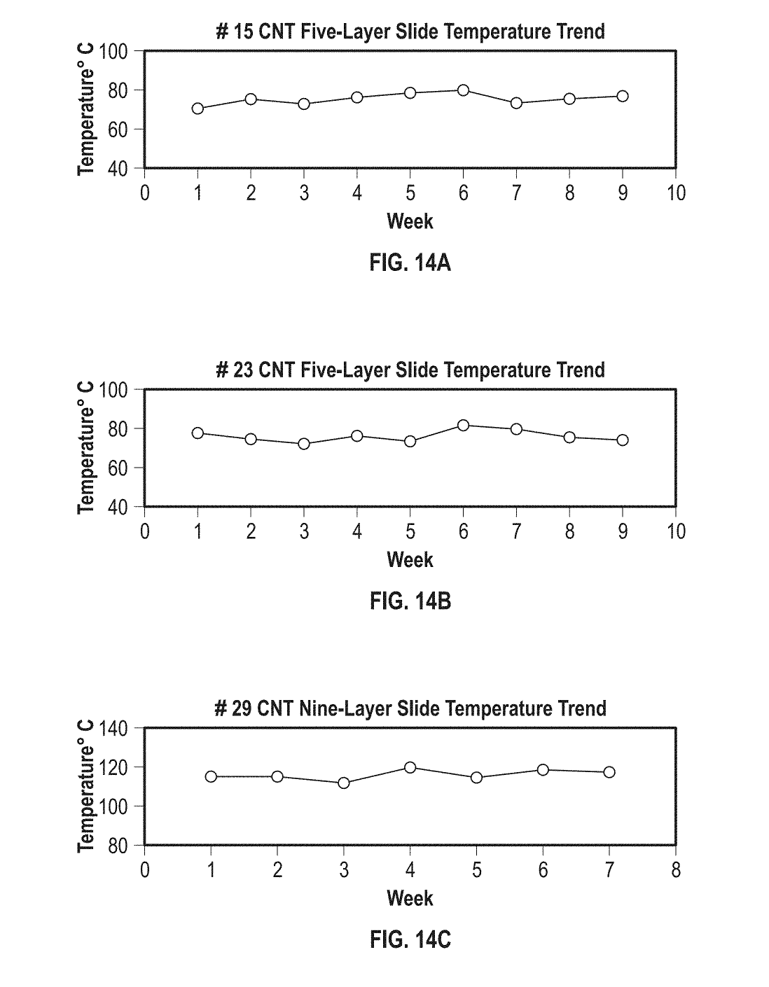

FIG. 14A, FIG. 14B, and FIG. 14C illustrate generally respective illustrative examples showing temperature versus time profiles for heating elements having different counts of layers of carbon nanotubes, where the trends are plotted over a longer time duration as compared to FIG. 13. To obtain the data plotted in FIG. 14A, FIG. 14B, and FIG. 14C, weekly lifetime performance tests were performed on two 5-layer slides and one 9-layer slide for nine weeks, under a constant applied voltage of 80 V. An average temperature of about 75° C. was obtained for the five-layer samples and about 115° C. for the nine-layer slides, respectively. To avoid lifetime degradation, the slide was coated with a cover layer, to isolate the CNTRENE™ layers from atmospheric contact. Such a cover layer can also be provided by sandwiching the CNT layer with another glass layer, or by using a protective inert coating such as acrylic, or by applying thermal tape, according to various examples. The repeatability of experimentally-obtained results described herein was assessed using range of different samples, including substrates comprising microscope slides, annealed glasses, laminated glasses, and tempered glasses (e.g., used to manufacture car windshields). Regardless of the glass sample, respective carbon nanotube coating configurations (e.g., layer count, processing conditions) generated a consistent resistance along with transmittance and other general properties.

An equation to determine the total power consumption (P) for operating a transparent (or other) heating element can be represented as,

P=V I EQN. 2

where V represents the voltage applied and I represents the current. A surface power density can be estimated using the following equation,

p_{d}=p/A EQN. 3

where A represents a CNT coated surface area (ignoring the area covered by electrodes). For 25 mm×25 mm and 25 mm×50 mm slides, the voltages to reach about 70° C. are about 60 V and about 80 V, respectively. The voltages can be multiplied by the measured current (0.02 A and 0.03 A respectively) to obtain the power. The surface power density determined EQN. 3 are about 0.24 watts/centimeter² for both samples. Such a value is approximate, as some non-uniformity in the temperature distribution over the coated area was observed. Similar manufacturing parameters have produced specimens having a similar surface power density, over a range of different surface areas. Once the power density is determined for the specific manufacturing parameters, it is possible to derive a suitable operating voltage for a specified area.

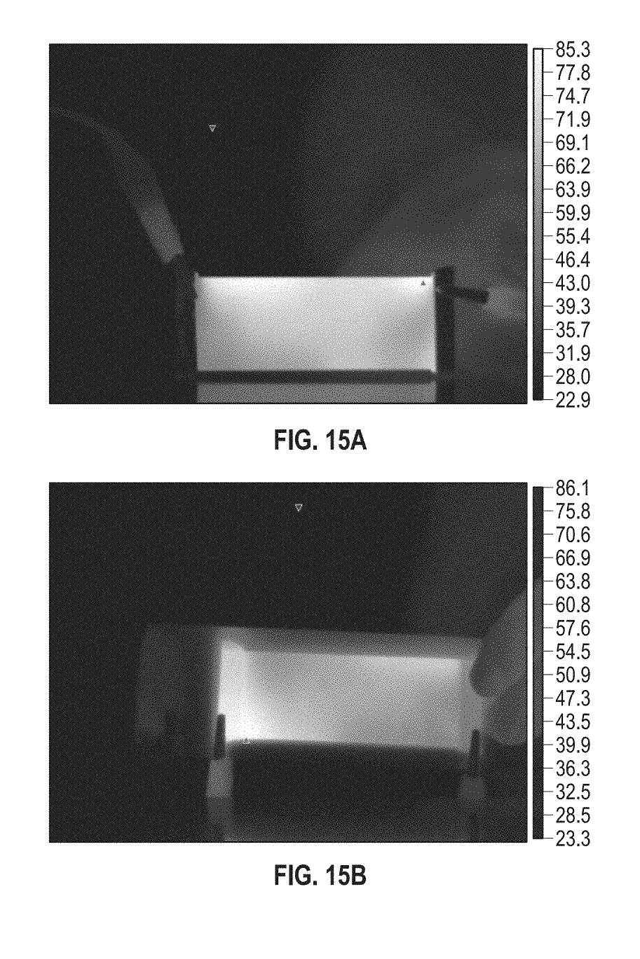

FIG. 15A and FIG. 15B illustrate generally respective infrared thermal images of an operating heating element, such as before application of a thermal tape in FIG. 15A, and after application of a thermal tape in FIG. 15B. A thermal tape comprising a flexible polymer film and adhesive can be used to protect a deposited CNT layer by creating isolation from the surrounding environment, such as suppressing oxidation or moisture exposure. A cover layer such as tape can also reduce hot spots, enhancing uniformity of heating. Hot spots are zones where the temperature is higher than other nearby areas. This is believed to be due to a presence of an increased number or density of carbon nanotubes in a particular zone. As shown in FIG. 15A as compared to FIG. 15B, use of a thermal tape as a cover layer generally reduces or suppresses hot spots.

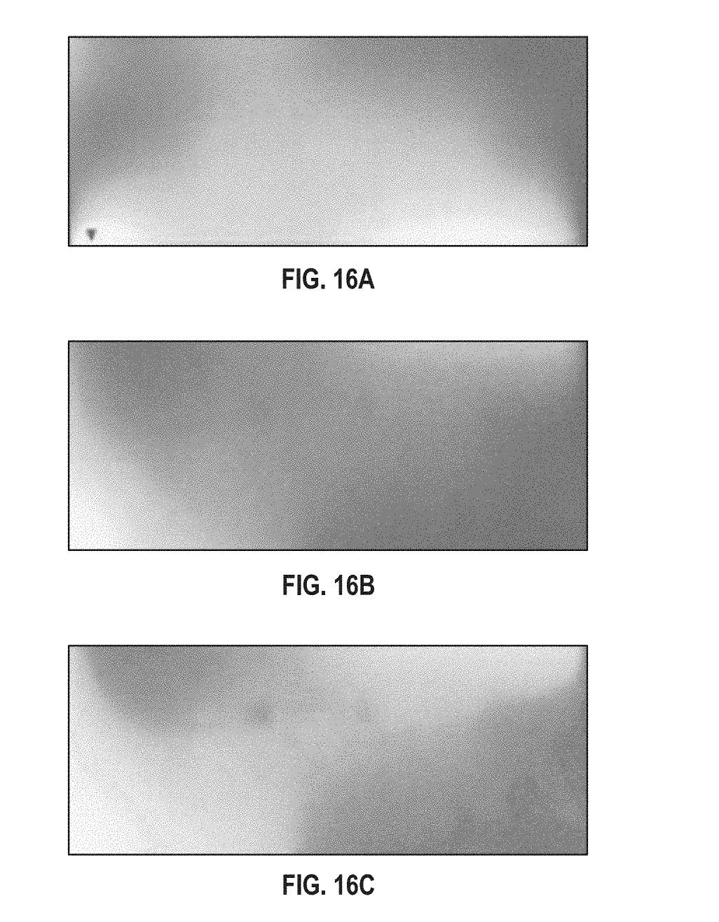

FIG. 16A, FIG. 16B illustrate generally respective infrared thermal images of an operating heating element, such as before application of a thermal tape in FIG. 16A, and after application of a thermal tape in FIG. 16B, and FIG. 16C shows a processed image calculating a difference between FIG. 16A and FIG. 16B at each spatial location, illustrating an improvement in thermal uniformity. A maximum temperature was generally attained at a contact point of a positive electrode and a minimum temperature was generally attained at contact point of the negative electrode. Without being bound by theory, it is believed that a source for the observed difference in temperature can be attributed to the Peltier effect, which is generally observed in semiconductors.

Other factors might affect formation of hot spots, such as electrode/CNT layer adhesion and uniformity of the deposited CNT layer. The Peltier effect is a thermoelectric phenomenon where some heat is transported as a thermoelectric interaction with the electrical current, in parallel with heat transport. The Peltier process can either increase or decrease the heat flux at a contact point included as a portion of an electrical circuit. In the example of FIG. 16A and FIG. 16B, the contact points are the electrodes. The Peltier effect is generally only about 5% efficient in thermoelectric reactions, and evidence of the effect was reduced after applying a thermal tape as a cover layer. A resultant image in FIG. 16C illustrates a difference between the before-tape and after-tape images of FIG. 16A and FIG. 16B, and illustrates generally where heat spots, possibly due to Peltier effect, have been reduced or suppressed. Pixel red-green-blue (RGB) values can be extracted from digital FLIR images. As shown in FIG. 16A and FIG. 16B, two images were obtained corresponding to a specimen before and after applying thermal tape, with the images having the same number of pixels. Pixel RGB values were then processed and compared to each other to generate the new resultant plot, corresponding to FIG. 16C, based on the change in RGB value.

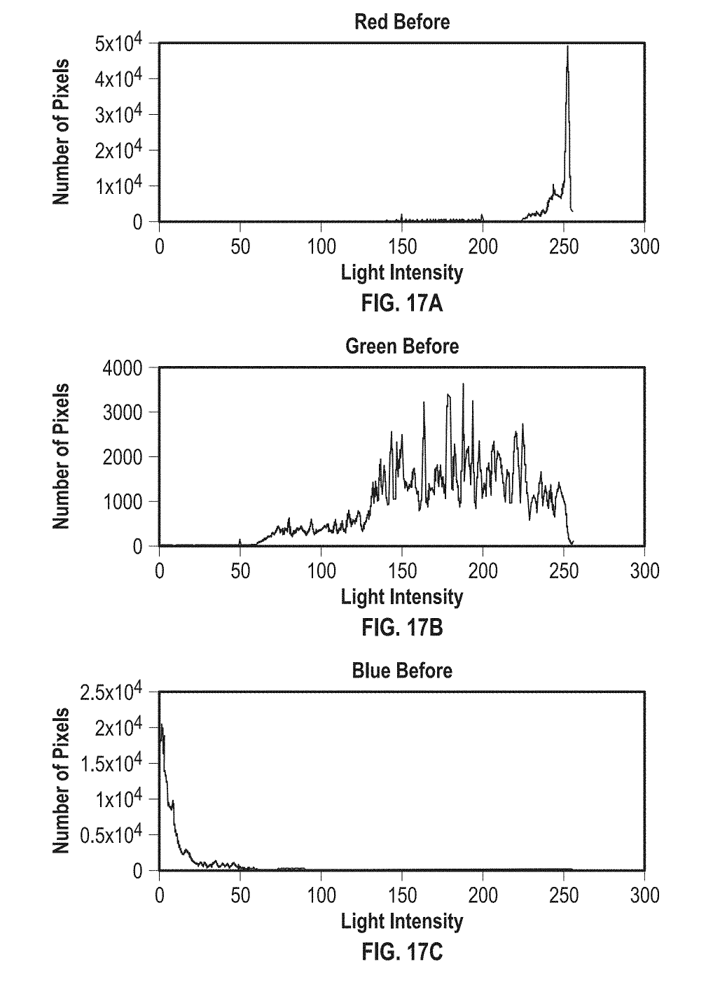

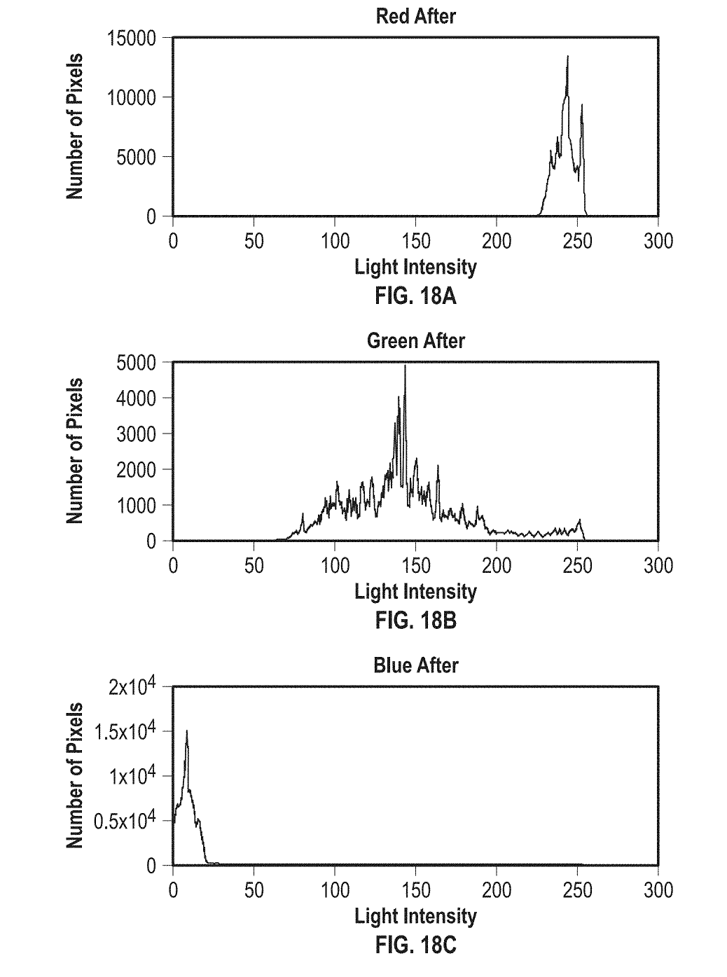

FIG. 17A, FIG. 17B, and FIG. 17C illustrate generally respective histogram plots of the thermal images of an operating heating element, such as corresponding to the image of FIG. 16A before application of a thermal tape and FIG. 18A, FIG. 18B, and FIG. 18C illustrate generally respective histogram plots of the thermal images of an operating heating element, such as corresponding to the image of FIG. 16B after application of a thermal tape. As mentioned above, a resultant plot showed the corrected heat spot and reduced Peltier effect. A population of pixel values can be used to generate histogram plots. Such histograms can be used to determine a difference in hot spot formation, and the illustrations of FIG. 17A, FIG. 17B, FIG. 17C, FIG. 18A, FIG. 18B, and FIG. 18C illustrate generally that use of thermal tape reduces hot spot formation (e.g., by showing a narrowing of the distributions and suppression or elimination of long tails).

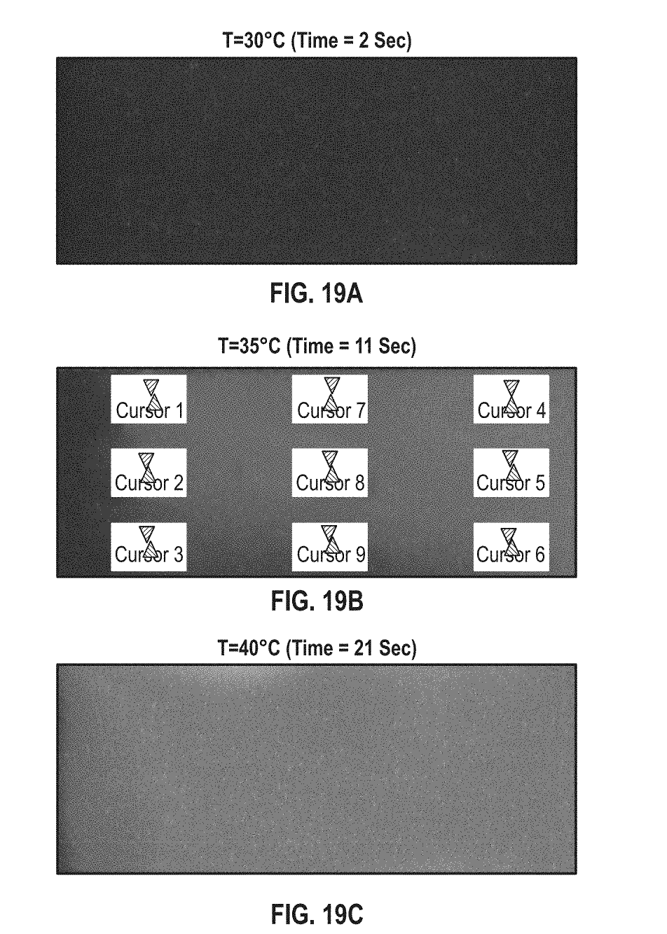

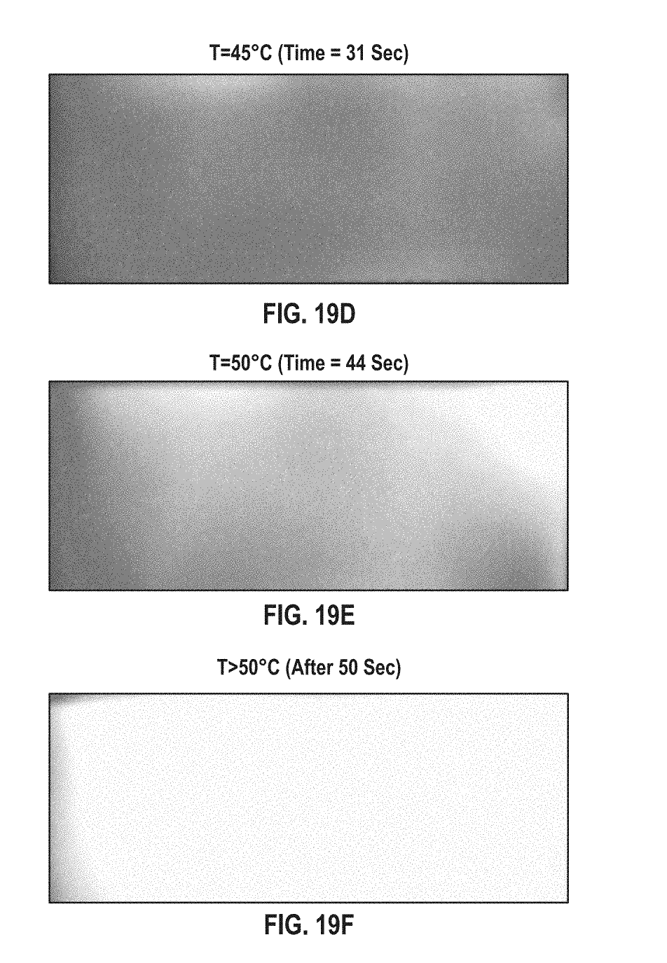

FIG. 19A, FIG. 19B, FIG. 19C, FIG. 19D, FIG. 19E, and FIG. 19F illustrate generally respective infrared thermal images of an operating heating element corresponding to various operating temperatures, where an individual thermal contour plot was generated to show the variation or change in temperature with respect to time, on a heating element clad with a cover layer of thermal tape. A temperature limit was set to 50° C., and for every 5° C. increase, an image was recorded, to provide the series of images shown in FIG. 19A, FIG. 19B, FIG. 19C, FIG. 19D, FIG. 19E, through FIG. 19F.

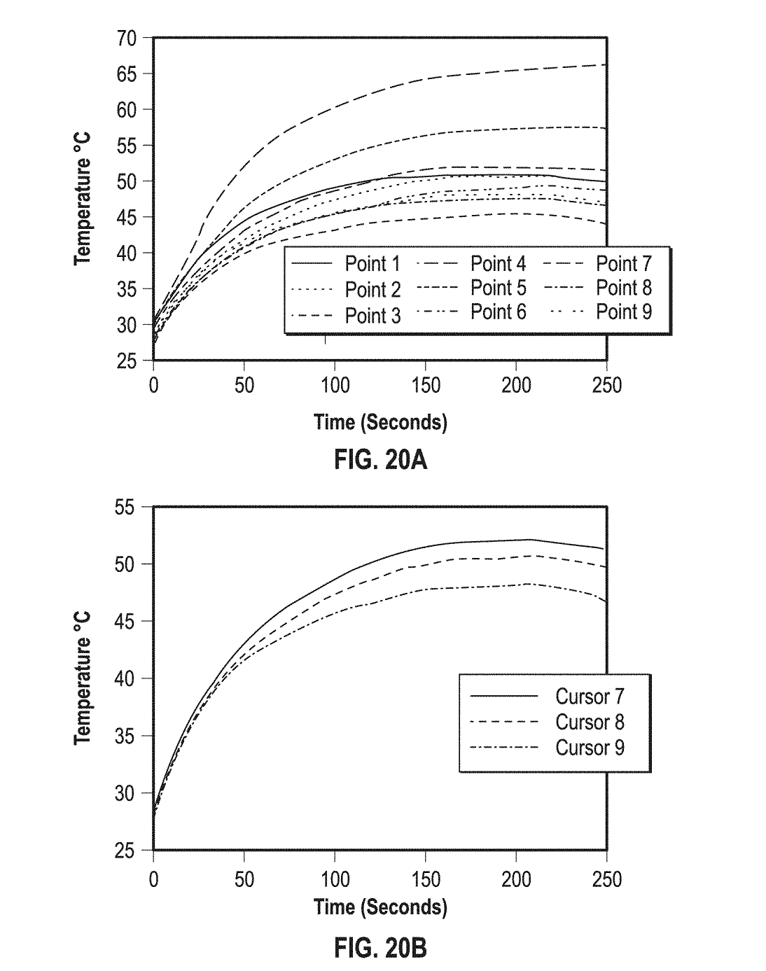

FIG. 20A and FIG. 20B illustrate generally temporal plots of temperature versus time for each of the spatial locations shown in FIG. 19B, where FIG. 20A includes each of the nine cursor locations (labeled as “Point” in FIG. 20A), and FIG. 20B includes a subset of the cursor locations. The locations of cursor numbers four and five are close to the positive electrode and experience relatively higher temperatures, and cursor numbers two and three are close to the negative and experience relatively lower temperatures. Excluding cursors two, three, four, and five (e.g., due to Peltier effect), all other cursors reflected a temperature uniformity of plus or minus 5° C. Use of a thermal tape as a cover layer can preserve optical transparency, while one or more of enhancing thermal uniformity or protecting a deposited CNT layer. Thermal tapes or other polymer materials can be tinted or can include various hues that can be specified for particular applications. Other examples of protective materials having varying degrees of longevity and immunity to contamination are mentioned in Longanathan, Santosh Kumar.

“Windshield defrost and deice using carbon nanotube composite,” Dissertation/Thesis: On Shelf, THESIS 2016 L64, ERAU Thesis Collection (December, 2016), which is hereby incorporated herein by reference in its entirety.

Each of the non-limiting aspects described in this document can stand on its own, or can be combined in various permutations or combinations with one or more of the other aspects or other subject matter described in this document.

The above detailed description includes references to the accompanying drawings, which form a part of the detailed description. The drawings show, by way of illustration, specific embodiments in which the invention can be practiced. These embodiments are also referred to generally as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” “one or more.” in this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMS), read only memories (ROMs), and the like.

The above description is intended to be illustrative, and not restrictive For example, the above-described examples (or one or more aspects thereof) may be used in combination with each other. Other embodiments can be used, such as by one of ordinary skill in the art upon reviewing the above description. The Abstract is provided to comply with 37 C.F.R. §1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

The claimed invention is:

1. A method, comprising:
depositing a solution on a substrate, the solution including carbon nanotubes, sulfur, and a solvent; and
drying the solution to provide a conductive layer on the substrate; and
forming two electrodes on the substrate in electrical contact with the conductive layer to provide a heating element.

2. The method of claim 1, comprising depositing multiple conductive layers comprising carbon nanotubes functionalized with sulfur on the substrate.

3. The method of claim 1, wherein depositing the solution comprises spin-coating the substrate with the solution.

4. The method of claim 1, wherein depositing the solution comprises spray-coating the substrate with the solution.

5. The method of claim 4, wherein the spray-coating includes use of a spray-pyrolysis technique.

6. The method of claim 1, wherein depositing the solution comprises dip-coating the substrate with the solution.

7. The method of claim 1, wherein the solution includes at east 75% single-walled carbon nanotubes (SWNT).

8. The method of claim 7, wherein the solution also includes double-walled nanotubes and multi-walled nanotubes.

9. The method of claim 7, wherein the solution includes ammonium hydroxide.

10. The method of claim 7, wherein at least a portion of the carbon nanotubes are functionalized with sulfur.

11. An electrical device, comprising:
a substrate;
a conductive layer including carbon nanotubes and sulfur, formed upon the substrate; and
two electrodes electrically coupled to the conductive layer, the two electrodes, when energized, configured to establish a current through the conductive layer to provide a heating element

12. The electrical device of claim 11, wherein the substrate and the conductive layer are optically transparent.

13. The electrical device of claim 11, wherein the substrate includes glass.

14. The electrical device of claim 11, comprising a cover layer located upon a surface of the conductive layer, opposite the substrate.

15. The electrical device of claim 14, wherein the cover layer comprises glass.

16. The electrical device of claim 14, wherein the cover layer comprises a flexible polymer.

17. The electrical device of claim 16, wherein the cover layer comprises an adhesive-backed film.

18. The electrical device of claim 11, wherein the conductive layer comprises a plurality of carbon nanotube layers formed upon the substrate, the carbon nanotube layers including sulfur.

19. An electrical device, comprising:
an optically-transparent substrate including glass;
an optically-transparent conductive layer including carbon nanotubes and sulfur, formed upon the substrate;
two electrodes electrically coupled to the optically-transparent conductive layer, the two electrodes, when energized, configured to establish a current through the conductive layer to provide a heating element; and
a cover layer located upon a surface of the conductive layer, opposite the substrate.

20. The electrical device of claim 19, wherein the cover layer comprises a flexible polymer.
